(19) United States
(12) Patent Application Publication
(10) Pub. No.: US 2007/0131771 A1
(43) Pub. Date: Jun. 14, 2007

(54) Driving method for solid-state image pickup device and image pickup apparatus

(75) Inventors: Yuzo Otsuru, Anpachi-Gun (JP); Kazutaka Itsumi, Kuwana-shi (JP)

Correspondence Address: OLIFF & BERRIDGE, PLC, P.O. BOX 19928, ALEXANDRIA, VA, 22320, US

(73) Assignee: SANYO ELECTRIC CO., LTD., MORIGUCHI-SHI (JP)

(21) Appl. No.: 11/605,215

(22) Filed: Nov. 29, 2006

(30) Foreign Application Priority Data
Nov. 30, 2005 (JP) 2005-346562

(51) Int. Cl. G06K 7/10

(52) U.S. Cl. 235/454; 235/462.41

(57) ABSTRACT

In an image pickup apparatus in which the potential well is shifted within each light receiving pixel of a CCD image sensor during an exposure period, blooming is suppressed. The CCD image sensor has a vertical overflow drain structure in which unnecessary information charges are discharged from the charge transfer channel region according to a substrate voltage Vsub. By switching a transfer electrode of a plurality of transfer electrodes for each pixel, to which an on-voltage is applied, during the exposure period, the accumulation position of the information charges is shifted, together with the potential well, within each pixel. The amount of information charge stored in the potential well, which exceeds a predetermined upper value of amount, is discharged by applying a discharge voltage V_{SH}, higher than a reference DC voltage V_{SL} in a normal state, to the substrate prior to the shift of the potential well.

### CROSS-REFERENCE TO RELATED APPLICATION

The priority application number JP2005-346562 upon which this patent application is based is hereby incorporated by the reference.

### FIELD OF THE INVENTION

The present invention relates to a solid-state image pickup device for generating information charges by receiving light by CCD shift registers and more particularly, to technology for suppressing blooming that occurs during an exposure period.

### BACKGROUND OF THE INVENTION

The solid-state image pickup device includes an image pickup section for generating and accumulating information charges for each pixel in response to light exposure, and a light-shielded storage section for storing the information charges that are received from the image pickup section at high speed until the information charges are read out line by line by a horizontal transfer section.

The image pickup section and the storage section each include a plurality of vertical CCD shift registers containing a plurality of charge transfer channel regions extended vertically being arranged parallel to one another, and a plurality of transfer electrodes extended horizontally being arranged parallel to one another. Each bit of the CCD shift register includes a plurality of transfer electrodes located adjacent to one another, and forms at each charge-transfer channel region one potential well for storing information charges as a result of voltage applied to the transfer electrodes. Each bit of the CCD shift register forms a pixel of the image pickup device.

The conventional driving circuit forms a potential well, which is fixed in position during the exposure period, in those bits of the CCD shift register of the image pickup section, and accumulates information charges depending on an amount of incident light. That is, on-voltage is applied to a particular transfer electrode corresponding to a clock of a certain phase among a plurality of transfer electrodes, which are driven by clocks having mutually displaced phases, of each bit, whereby a potential well is formed under the particular transfer electrode.

FIG. 1 is a view schematically showing potential wells during the exposure period in a conventional driving method when the image pickup section is formed by three-phase CCD shift registers. As shown, transfer electrodes 3-1 to 3-3 to which clock pulses φi1, φi2 and φi3 are applied are periodically arranged on a charge transfer the charge transfer channel region 2. A trio of transfer electrodes 3-1 to 3-3 successively arranged corresponds to one pixel. In FIG. 1, lens elements 4 forming a micro-lens array are located above the transfer electrodes 3-1 to 3-3 corresponding to one pixel. During the exposure period, on-voltage is applied to the transfer electrode 3-2 located at the center of the pixel corresponding to the lens center, and off-voltage is applied to the remaining transfer electrodes 3-1 and 3-3, thus forming a potential well 5 under the transfer electrode 3-2. Information charges 6 that are generated in response to incident light are accumulated in the potential well 5.

In the charge-transfer region 2, a dark current occurs, for example, due to the effect of an interface state in the vicinity of a surface of a semiconductor substrate. The potential well 5 formed during the exposure period accumulates not only information charges 6 produced in correspondence with an incident ray but also a dark current generated at a corresponding region. The dark current is one of the factors causing deterioration of the S/N ratio. An amount of the dark current depends on uncontrollable factors, such as the interface state, and may fluctuate from place to place in the charge transfer channel region. With conventional driving methods, the dark current mixed into the information charges of each pixel is the dark current mainly generated at the potential well forming location, i.e., the transfer electrode applied with the on-voltage (transfer electrodes 3-2, for example). The potential wells are formed and arranged at intervals each equal to the width of two transfer electrodes. Accordingly, the dark current mixed into each potential well is relatively susceptible to the position-dependent variations of the amount of dark current. In the conventional technology, image noise, which is due to the variation of the dark current component for each pixel, tends to be large, which increases granularity of the image and gives a visual impression that the image appears rough.

To cope with this problem, a driving method is proposed in which by switching an on-electrode, forming the potential well, of those transfer electrodes 3-1 to 3-3 of each pixel during the exposure period, and as the potential well shifts, an accumulation position to which the information charges are accumulated is shifted within the pixel. FIG. 2 is a view schematically showing a driving method in which the potential well formed in the image pickup section is shifted during the exposure period. The figure illustrates the time variation of the potential well formed in the charge transfer channel region. A trio of transfer electrodes G1 to G3 is periodically arranged on the charge transfer channel region. The trio of transfer electrodes G1 to G3 is allotted to each light receiving pixel. The potential well 60 formed under the transfer electrode G2 shifts, with time, a potential well 62 under the transfer electrode G1, a potential well 64 under the transfer electrode G2 and a potential well 66 under the transfer electrode G3. Since the potential well is shifted within the pixel during the exposure period, the dark current components are accumulated at different locations within the pixel. The dark current components accumulated within the pixel are positionally averaged in amount in the pixel. As a result, a variation of the dark current components among the pixels is suppressed and hence, the granularity noise of the image is reduced.

The application of the on-voltage to the two transfer electrodes adjacent to each other is timed for when the potential well is shifted within the pixel during the exposure period (the states (b), (d) and (f) in FIG. 2). At those timings, the potential wells formed under the two transfer electrodes are separated by a potential barrier that is formed under one transfer electrode. With reduction in size of the pixel, the channel length under each transfer electrode becomes shorter. Because of the short channel effect, the potential barrier formed by applying the off-voltage to only one transfer electrode tends to be lower than a potential barrier, for example, formed by applying the off-voltage to the two transfer electrodes adjacent to each other. FIG. 3 is a view schematically showing states of potential wells when the short channel effect is taken into consideration. In FIG. 3, a channel potential 7-1 indicated by a solid line corresponds to a state (b) in FIG. 2 and the channel potential 7-2 indicated by a dotted line corresponds to a state (a) in FIG. 2. As seen from the figure, the potential barrier 8-1 formed by only one transfer electrode G3 is lower than the potential barrier 8-2 formed by the two transfer electrodes G3 and G1. Where the driving method in which the potential well is shifted within the pixel is employed, blooming tends to occur at the time when the two adjacent transfer electrodes are concurrently put in an on state due to the lowering of the potential barrier.

### SUMMARY OF THE INVENTION

In a driving method for a solid-state image pickup device and an image pickup apparatus which suppresses granularity noise of an image in such a way that the information charges are accumulated while the potential well is shifted within a pixel during the exposure period, the present invention suppresses the blooming adequately to provide an excellent image.

According to the present invention, there is provided a driving method for a solid-state image pickup device, the image pickup device being provided with an image pickup section containing CCD shift registers for accumulating information charges generated in response to light exposure in potential wells that are formed, corresponding to a plurality of pixels, by using a plurality of transfer electrodes arranged on a charge transfer channel region and a drain structure for discharging unnecessary information charges from the charge transfer channel region into the drain region in response to an applied discharge voltage. The driving method includes an accumulation position shift process in which an on-electrode for forming the potential well in each pixel is changed within an exposure period among the plurality of transfer electrodes positioned at the pixel, to shift the accumulation position to which the information charges are accumulated within the pixel in response to shifting of the potential well formed by the on-electrode and a discharge process in which the discharge voltage is applied within the exposure period to the drain structure prior to execution of the accumulation position shift process, to discharge surplus information charges which exceed a predetermined upper limit of the amount of the information charges stored in the potential well.

The image pickup apparatus has a solid-state image pickup device including CCD shift registers for accumulating information charges generated in response to light exposure in potential wells that are formed, corresponding to a plurality of pixels, by using a plurality of transfer electrodes arranged on a charge transfer channel regions and a drain structure for discharging unnecessary information charges, of the information charges, from the charge transfer channel region into the drain region in response to an applied discharge voltage, and a driving circuit for driving the solid-state image pickup device. The driving circuit performs a accumulation position shift operation in which an on-electrode for applying on-voltage to each pixel is changed within an exposure period among the plurality of transfer electrodes positioned at the pixel, to shift the accumulation position to which the information charges are accumulated within the pixel in response to shifting of the potential well formed by the on-electrode. Furthermore, the driving circuit performs a discharge operation in which the discharge voltage is applied within the exposure period to the drain structure prior to execution of the accumulation position shift operation, to discharge surplus information charges which exceed a predetermined upper limit of the amount of the information charges stored in the potential well.

### BRIEF DESCRIPTION OF THE DRAWINGS

FIG. 1 is a view schematically showing potential wells during the exposure period in a conventional driving method when the image pickup section is formed by three-phase CCD shift registers;

FIG. 2 is a view schematically showing potential wells formed in the an image pickup section during an exposure period E;

FIG. 3 is a view schematically showing states of potential wells when the short channel effect is taken into consideration;

FIG. 4 is a block diagram showing a configuration of an image pickup apparatus according to an embodiment of the present invention;

FIG. 5 is a plan view schematically showing a part of the image pickup section;

FIG. 6 is a cross sectional view taken on line A-A′ in FIG. 5, in the charge transfer direction of the CCD shift register of the image pickup section;

FIG. 7 is a graph showing potential profiles in the CCD shift register shown in FIG. 6 as viewed n the substrate depth direction; and

FIG. 8 is a timing chart showing basic shifts of various voltage signals that the clock generation circuit supplies to the image sensor.

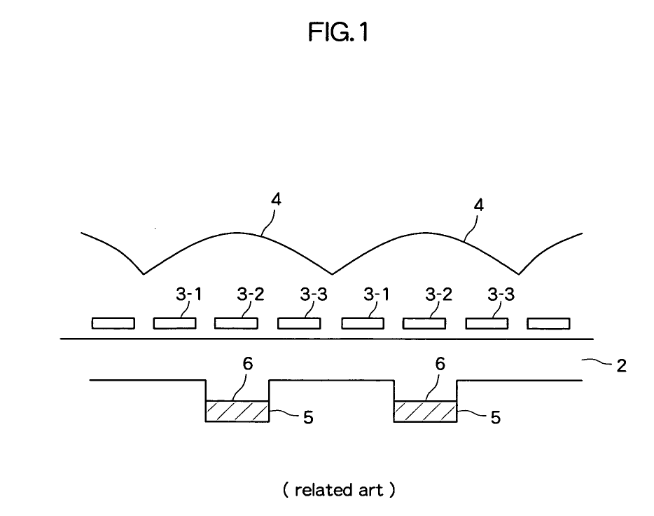

### DESCRIPTION OF THE PREFERRED EMBODIMENTS

The preferred embodiments of the present invention will be described with reference to the accompanying drawings.

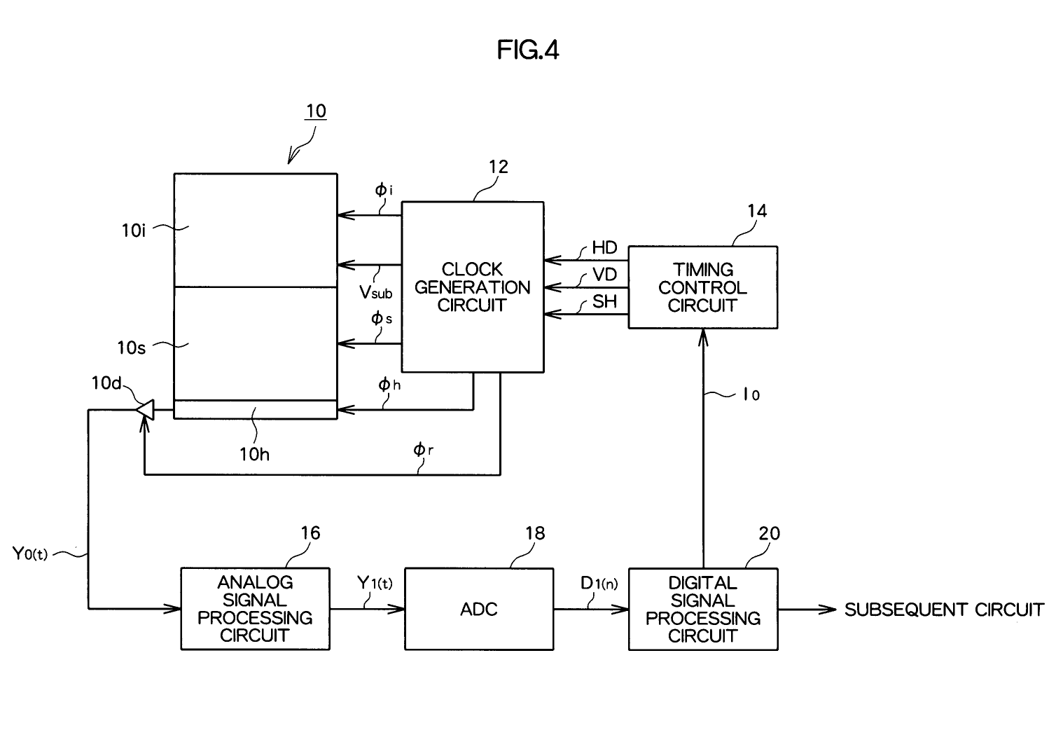

FIG. 4 is a block diagram showing a configuration of an image pickup apparatus according to an embodiment of the present invention. The image pickup apparatus is made up of an image sensor 10, a clock generation circuit 12, the timing control circuit 14, an analog signal processing circuit 16, an A/D converter circuit 18 and a digital signal processing circuit 20.

The image sensor 10 is a frame transfer CCD image sensor and includes an image pickup section 10i, a storage section 10s, a horizontal transfer section 10h and an output section 10d, all formed on a surface of a semiconductor substrate. The image pickup section 10i and the storage section 10s are each vertical CCD shift registers, which are arrayed in a line direction (horizontal direction on an image). Each of the imaging section 10i and the storage section 10s has a plurality of vertical CCD shift registers arranged in a line direction (a horizontal direction of an image). Each of the vertical CCD shift registers of the imaging section 10i and each of the vertical CCD shift registers of the storage section 10s are arranged in a column direction and have a consecutive channel. Those vertical CCD shift registers are provided with a plurality of gate electrodes as transfer electrodes, which extend on the substrate in the line direction and arranged parallel to one another and in the column direction. By applying clock signals of plural phases, which are shifted from one another, to those charge transfer electrodes, the information charge of each pixel is vertically transferred through the vertical CCD shift registers. In the image sensor 10, the CCD shift registers of the image pickup section 10i and the storage section 10s are of the three-phase driving type. The image pickup section 10i is supplied with a three-phase clock φi and the storage section 10s is supplied with a three-phase clock φs, whereby storage and transfer of the information charges are respectively controlled.

Light receiving pixels formed with the bits of the vertical CCD shift registers of the image pickup section 10i generate charge according to incident light and accumulate signal charges. The information charge accumulating operation in the image pickup section 10i will be subsequently described. After a predetermined period of exposure time elapses, the vertical CCD shift registers of the image pickup section 10i and the storage section 10s are driven by the three-phase clock signals φi and φs and the frame transfer from the image pickup section 10i to the storage section 10s is performed. The storage section 10s is covered with a light shielding film to prevent charge generation by incident light. Accordingly, the storage section 10s is able to store the signal charges frame transferred from the image pickup section 10i. The horizontal transfer section 10h is a CCD shift register having bits respectively coupled to the output terminals of the vertical CCD shift registers of the storage section 10s. The signal charges of one screen, stored in the storage section 10s, are line transferred to the horizontal transfer section 10h line by line. The signal charges, which have reached the horizontal transfer section 10h, are transferred to the output section 10d by the horizontal transfer driving of the horizontal transfer section 10h. The output section 10d includes an electrically isolated capacitor and an amplifier for extracting a potential change of the capacitor. The output section 10d receives the signal charge received from the horizontal transfer section 10h via the capacitor bit by bit, converts it into a voltage value, and outputs the voltage value in the form of a time sequential image signal Y0(t).

The clock generation circuit 12 generates a clock φi for driving the vertical shift register of the image pickup section 10i, a clock φs for driving the vertical shift register of the storage section 10s, a clock φh for driving the horizontal transfer section 10h, a clock φr for driving a reset gate of the output section 10d and a substrate voltage Vsub to be applied to an n-type semiconductor substrate, thereby driving the image sensor 10. The clock generation circuit 12 operates according to timing signals supplied from the timing control circuit 14.

The timing control circuit 14 comprises a plurality of counters, each for counting a reference clock signal CK with a constant cycle, and dividing a reference clock signal CK to generate timing signals such as a horizontal synchronizing signal HD and a vertical synchronizing signal VD.

The analog signal processing circuit 16 applies processes of sample and hold, AGC (automatic gain control), etc., to the image signal Y0(t) to generate an image signal Y1(t) having a given format.

The A/D (analog-to-digital) converter 18 converts an analog image signal Y1(t), which comes from the analog signal processing circuit 16, into a digital signal and outputs the converted signal as image data D1(n).

The digital signal processing circuit 20 receives the image data D1(n) from the A/D converter 18 and variously processes the image data D1(n). For example, the digital signal processing circuit 20 generates luminance data and color data from the image data D1(n), and processes the generated data for contour correction and gamma correction. The digital signal processing circuit 20 contains an automatic exposure control circuit and integrates the image data for each screen and enlarges and reduces the period of exposure time E according to the resultant integrated value. The automatic exposure control circuit designates the exposure period E by using an exposure control value Io with a horizontal scanning period (1H) as a unit.

FIG. 5 is a plan view schematically showing a part of the image pickup section 10i. The light receiving pixels respectively correspond to the bits of the vertical shift registers, and are capable of accumulating information charges of one pixel. Channel stop regions 30s separate channel regions 30c of the vertical shift registers. Transfer electrodes G1 to G3 (transfer electrodes 32-1 to 32-3) are periodically arranged in the column direction on the channel regions 30c extending in the column direction. A trio of transfer electrodes 32-1 to 32-3 is arranged on each of light receiving pixels 34. The transfer electrode 32-2 is located on the pixel located on the central part of the pixel. The transfer electrodes 32-1 to 32-3 receive the clock signals φi1 to φi3 from the clock generation circuit 12.

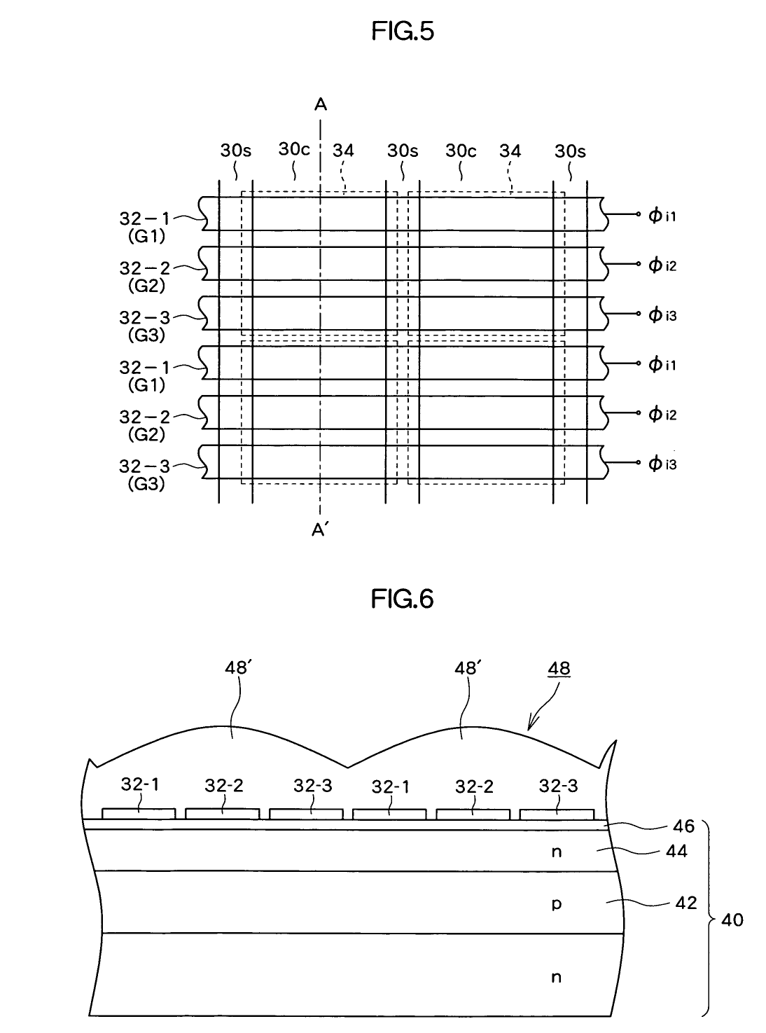

FIG. 6 is a cross sectional view taken on line A-A′ in FIG. 5. More exactly, in the drawing, the image pickup section 10i is cut in the charge transfer direction of the CCD shift register. An n-type semiconductor substrate 40 is used, for example. A p-well 42 is formed by diffusing p-type impurities into the n-type semiconductor substrate 40. An n-well 44 is formed by diffusing n-type impurities into the n-type semiconductor substrate 40 to a depth level that is lower or shallower than the p-well 42. As a result, the CCD shift register becomes a buried channel CCD. Further, the n-well 44 and the p-well 42 form an npn structure in the depth direction in the semiconductor substrate 40, thereby forming a vertical overflow drain (VOD). The transfer electrodes 32-1 to 32-3 are formed on surface of the substrate with a gate oxide film 46 being inter-layered there between. The three-phase clock signals φi1 to φi3 are applied to the transfer electrodes 32-1 to 32-3. The channel potential within the semiconductor substrate under the gate oxide film 46 is controlled by the clock voltages. A microlens array 48 is also illustrated in FIG. 6. Lens elements 48′, which form the microlens array 48, are located corresponding in position to the light receiving pixels and collects the rays of light incident on the lens elements 48′ toward the light receiving pixels.

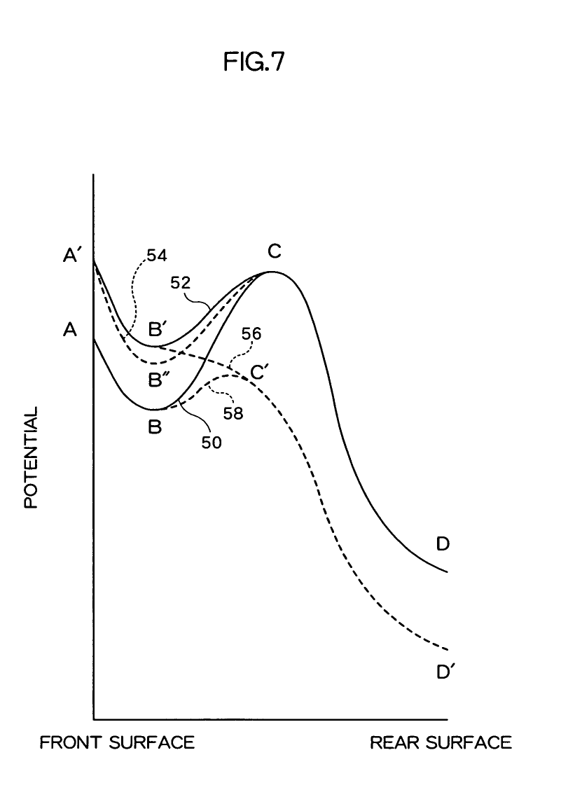

FIG. 7 is a graph showing potential profiles in the CCD shift register shown in FIG. 6, as viewed in the depth direction. In the figure, the abscissa represents a depth of the semiconductor substrate, while the ordinate represents potential in the semiconductor substrate. In the figure, the downward direction is a positive potential direction and the upward direction is a negative potential direction. Curve 50 (curve ABCD) and curve 52 (curve A′B′CD) represent potential profiles when one of the transfer electrodes 32 for one pixel is an on-electrode to which an on-voltage of a transfer clock signal is applied, and the remaining two transfer electrodes are off-electrodes to which an off-voltage of a transfer clock signal is applied. More simply, the curve 50 (curve ABCD) represents a potential profile under the on-electrode and the curve 52 (curve A′B′CD) represents a potential profile under the off-electrodes. Point B on the curve 50 indicates an electrical potential of the potential well. Point B′ on the curve 52 indicates a potential at a saddle point of a potential barrier formed between the potential wells. A Curve 54 (curve A′B″CD) indicates the potential profile under the off-electrodes during the shift of the potential well. During the shift of the potential well, two transfer electrodes 32 of each pixel are on-electrodes and the remaining one transfer electrode 32 is the off-electrode. Accordingly, the short channel effect acts, and the potential at point B″ is affected by the potential of the potential well under the on-electrodes on both sides, becoming deeper than point B′. In shifting of the potential well, the height of the potential barrier separating the potential wells at the time when the two transfer electrodes 32 become on-electrodes, is lower than the height of the potential barrier at the time when only one transfer electrode 32 becomes the on-electrode. As a result, a phenomenon called blooming, where the information charge stored in the potential well moves over the potential barrier and flows into its adjacent potential well, is easy to occur.

The on-voltage is set at a predetermined positive voltage V_{H}. The off-voltage is set at a predetermined negative voltage V_{L2} for the CCD shift registers of the image pickup section 10i during the exposure period. On the other hand, for the CCD shift registers of the image pickup section 10i during periods other than the exposure period and the CCD shift registers of the storage section 10s, the off-voltage is set at a predetermined negative voltage V_{L1}, higher than the voltage V_{L2}. For example, the voltage V_{L2} is set at a voltage for pinning the potential on the substrate surface under the transfer electrode to which that voltage is applied. An inversion layer in which holes supplied from the channel stop regions 30s are accumulated is provided on the substrate surface in a pinned state. In a state where the substrate surface is inverted by the holes, generation of the thermally excited electrons is suppressed in an interface region where it contacts the gate oxide film. Since, for example, a density of free holes in a valence band is large at the inverted interface, the rate at which the interface state produced at the interface between the substrate and the gate oxide film captures the holes becomes higher. Electrons that have been excited from the valence band to an interface state capture holes and are easy to return to the valence band. As in this pinned state, electrons are difficult to excite into the conduction band under the transfer electrode to which a negative off-voltage is applied, and hence the dark current based on the interface state is suppressed.

In FIG. 7, curve 56 (curve A′B′C′D′), indicated by a dotted line, indicates the potential profile during an electronic shutter operation. In the electronic shutter operation, an off-voltage is applied to all the transfer electrodes of the image pickup section and the substrate voltage Vsub is set at a positive voltage (point D′), higher than a normal voltage (point D). When the substrate voltage Vsub is increased, the potential of the p-well 42, which is normally located at point C, lowers to point C′, whereby the potential barrier existing in the substrate depth direction, formed by the p-well 42, disappears. As a result, it is possible for the information charges on the obverse surface of the substrate to move over the p-well 42 to the reverse surface thereof.

In the instant image pickup apparatus, a blooming suppression operation for discharging information charges is performed in order to suppressing blooming. In the blooming suppression operation, the substrate voltage Vsub is set at a positive voltage (point D′), higher than the normal voltage (point D), in a state where the on-voltage is applied to the transfer electrode corresponding to the potential well for storing the information charges. The potential profile under the on-electrode during the blooming suppressing operation is depicted as curve 58 (curve ABC′D′) and the potential profile under the off-electrode is as curve 56 (curve A′B′C′D′). Accordingly, of the information charges stored in the potential well, the amount of information charge exceeding the potential (point C′) of the p-well 42 is discharged to the reverse surface of the substrate. The substrate voltage Vsub is selected to deepen the potential (point C′) of the p-well 42 beyond point B″. Thus, the amount of information charge stored in the potential well is reduced to be below the potential barrier (point B″) under the off-electrode during the shifting of the potential well before the potential well shifts. As a result of this unique technical idea of the invention, it is difficult for blooming to occur.

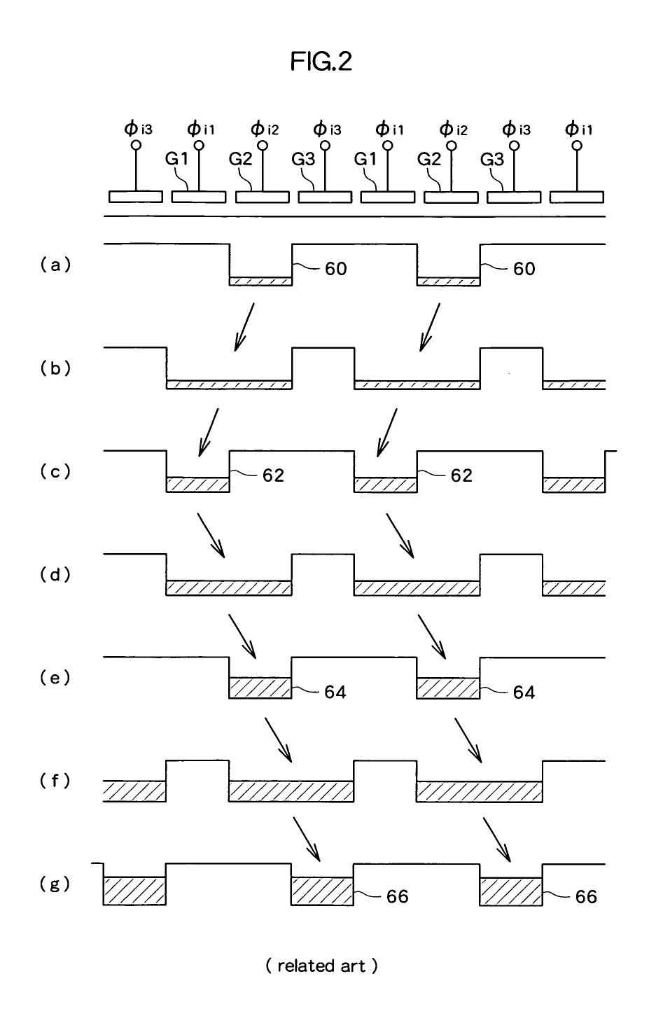

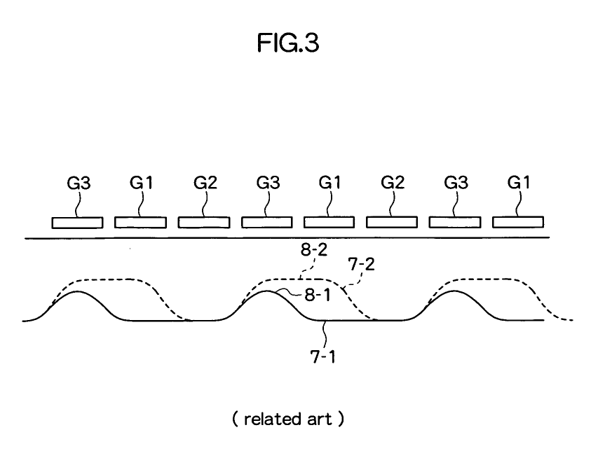

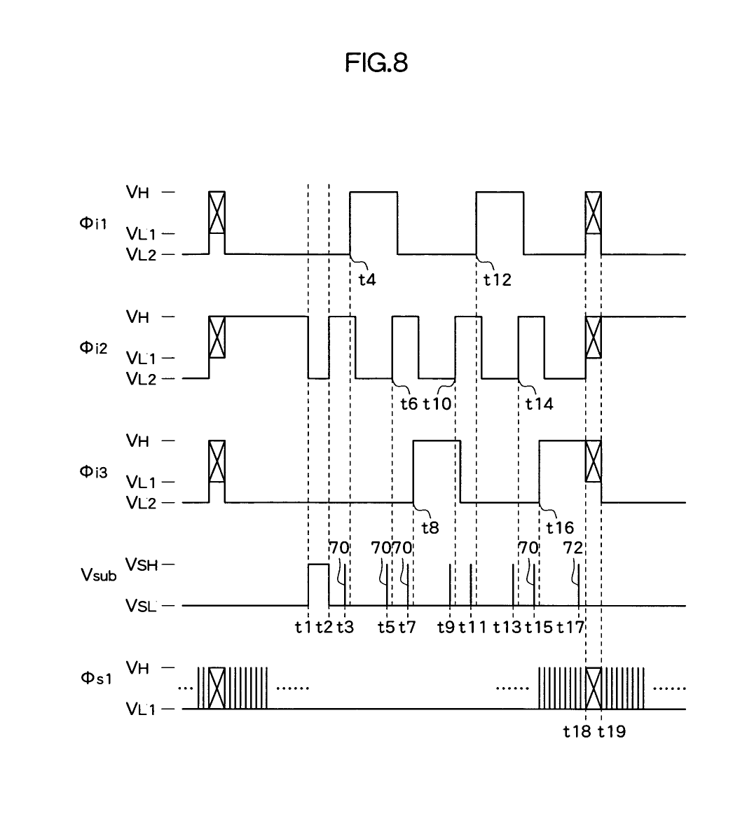

A method of driving the image sensor in the image pickup apparatus will now be described. FIG. 8 is a timing chart showing basic shifts of various voltage signals that the clock generation circuit 12 supplies to the image sensor 10. In FIG. 8, the axis of abscissa represents time. On the ordinate axis in FIG. 8, the voltage increases in amplitude in an upward direction. FIG. 8 illustrates in schematic form the waveforms and generation timings of the transfer clock signals φi1 to φi3 to be applied to the transfer electrodes of the image pickup section 10i, the substrate voltage Vsub and the transfer clock signal φs1 to be applied to the storage section 10s. The remaining transfer clock signals φs2 and φs3 are omitted from the figure since those signals are substantially the same as the transfer clock signal φs1 except that the phases of φs2 and φs3 are different from that of φs1. The present image pickup apparatus employs the driving method in which the information charge accumulation position is shifted within each pixel during the exposure period of time already described in connection with FIG. 2. Description will be given referring also to FIG. 2, which is a model diagram showing the potential wells formed in the image pickup section 10i during the exposure period E.

To acquire an image of one screen, the image pickup section 10i is first exposed. The exposure period E is controlled through the electronic shutter operation. In the electronic shutter operation, the clock signals φi1 to φi3 applied to the transfer electrodes G1 to G3 located in the image pickup section 10i are all set at the off-voltage for a predetermined period of time (t1 to t2). Furthermore, during this period the substrate voltage Vsub is set at the discharge voltage V_{SH}, which is higher than a reference DC voltage V_{SL} as a DC voltage applied in a normal state. The reference DC voltage V_{SL} corresponds to the voltage at the point D in FIG. 7 and the discharge voltage V_{SH} corresponds to the voltage at the point D′ in FIG. 7. As a result, the information charges stored in the channel region in the image pickup section 10i are discharged to the reverse surface of the substrate.

At a time t2 when the electronic shutter operation ends, a clock signal φi of a predetermined phase, for example, a clock signal φi2, is put to an ON-state. In the image pickup section 10i, the potential well 60 is formed under the transfer electrode corresponding to that clock signal (the state (a) in FIG. 2). The exposure period E starts from this time. The time when the exposure period E ends is determined by the time t18 of the start of the frame transfer.

The image pickup apparatus shifts the potential well within a pixel during the exposure period E. During each exposure period, potential wells are formed respectively during the same time period under the three transfer electrodes G1-G3 positioned at each pixel. Specifically, the clock generation circuit 12 keeps the transfer clock signal φi2 at the on-voltage during a time period α from the time t2. The result is that a potential well 60 is formed under the transfer electrode G2 and information charges whose amount is defined by the period a are accumulated in the potential well 60 (the state (a) in FIG. 2). Then, the transfer clock φi1 is put to the on-voltage for a time period 2α from the time t4 preceding the end of the on-voltage of φi2 by a predetermined period P. As a result, the information charges stored under the transfer electrode G2 move to a potential well 62 formed under the transfer electrode G1 and information charges generated under the transfer electrode G1 are furthermore accumulated for the duration 2α (the states (b) and (c) in FIG. 2). Then, the transfer clock φi2 is again set to the on-voltage for a time period α from the time t6 preceding the end of the on-voltage of φi1 by a predetermined period β. As a result, the information charges stored under the transfer electrode G1 move to a potential well 64 formed the transfer electrode G2 and the information charges generated under the transfer electrode G2 are accumulated in the potential well for the duration α (the states (d) and (e) in FIG. 2). Further, the transfer clock φi3 is set to the on-voltage for a time period 2α from the time t8 preceding the end of the on-voltage of φi2 by a predetermined period β. As a result, the information charges stored under the transfer electrode G2 move to a potential well 66 formed anew under the transfer electrode G3 and information charges generated under G3 are accumulated in the new potential well for the duration 2α (the states (f) and (g) in FIG. 2). One to several cycles of the potential well shifts are performed during the time period ranging from the electronic shutter operation to the frame transfer. Here, one cycle consists of a sequence of operations in which the potential wells are formed sequentially under the transfer electrodes G2, G1, G2, and G3. In the example of FIG. 8, two cycles of the potential well shifts are performed. The potential well sequentially shifts to under the transfer electrodes G2, G1, G2, and G3 at times t10, t12, t14 and t16, as at the times t2, t4, t6 and t8.

Through the operations above, the period that the potential well is formed under each of the transfer electrodes G1 to G3 during the exposure period E is 2α for each cycle. Thus, regarding dark current contained in the information charges of each pixel transferred to the storage section 10s, the amounts of the dark currents accumulated under the respective electrodes G1-G3 are the same in response to accumulation periods equal to each other. The dark currents at the positions in the pixel are averaged to suppress variations of the dark currents among the pixels.

The off-voltage of each CCD shift register in the image pickup section 10i during the exposure period, already described, is set at the V_{L2}, lower than the off-voltage V_{L1} during another exposure period. As a result, the dark current components accumulated in the pixels are reduced, as described above.

The information charges stored in the potential well 66 under the transfer electrode G3 are transferred at high speed to the storage section 10s by the frame transfer operation starting from the time t18. The clock generation circuit 12, during the frame transfer operation, generates high-speed clock signals as the transfer clock signals φi (φi1 to φi3) and φs (φs1 to φs3) by cycles corresponding to the number of pixels arrayed in the column direction in the image pickup section 10i (period from times t18 to t19). The high-speed clock signals each have an amplitude ranging from V_{L1} to V_{H} and are synchronized with one another. As a result, the signal charges of all the pixels in the image pickup section 10i are transferred to the storage section 10s with the shielding film for a short time. The information charges having been transferred to the storage section 10s are transferred to the horizontal transfer section 10h through the line transfer operation. The clock generation circuit 12 generates a transfer clock signal φs of one cycle at timings synchronized with a horizontal synchronization signal HD generated by the timing control circuit 14 and executes the line transfer operation. The clock signals of the transfer clock signal φs for the line transfer each oscillate between the voltages from V_{L1} and V_{H}. The horizontal transfer section 10h transfers the information charges to the output section 10d by the horizontal transfer and the output section 10d converts the information charges into an image signal Y0(t) and outputs it sequentially.

When the potential well is shifted from one transfer electrode to another transfer electrode during the exposure period E, the time period β exists in which the transfer electrode from which the potential well is shifted and the transfer electrode to which the potential well is shifted simultaneously receive the on-voltage. During this period β, the potential barrier is formed by only one transfer electrode and with lowering of the potential barrier, blooming tend to occur. To cope with this, the image pickup apparatus executes the blooming suppressing operation prior to the period β. Specifically, in the case of FIG. 8, discharge voltage V_{SH} is generated by superposing a pulse 70 on the reference DC voltage V_{SL} of the substrate voltage Vsub, and is applied to the substrate prior to times t4, t6, t8, t10, t12, t14 and t16 at which the period β starts. As a result, the potential of the p-well 42 becomes a potential (point C′ in FIG. 7) which is deeper than the potential in a normal state (point C in FIG. 7). Of the information charges stored in the potential well, the charges exceeding the potential (point C′) in the p-well 42 are discharged to the reverse surface of the substrate. Thus, the information charges stored in the potential well are reduced prior to the period β during which the potential well shifts, so that blooming is unlikely to occur during the period β.

During a period from the pulse 70 to the start of the period β, the information charges generated anew are accumulated in the potential well of the image pickup section 10i. With an increase of the period β, the discharging effect of the information charges caused by the blooming suppressing operation may be reduced. For this reason, it is preferable that the pulse 70 is superposed on the reference DC voltage just before the period β.

The pulse 70 may be generated only for some of the periods β that may exist during the exposure period. For example, in the potential well shift in FIG. 8, the time period allowing the potential well to continuously exist under the transfer electrodes G1 and G3 is 2α. This period is longer than the time period α where the potential well continuously exists. Accordingly, an increase of the information charge during the time period when the potential wells are present under the transfer electrodes G1 and G3 is generally larger than an increase of the information charge under the transfer electrode G2. It is conceivable that the blooming may easily occur when the potential well shifts to under the transfer electrode G2, the shift starting at times t6, t10 and t14. To avoid this, it may be designed that only the pulses 70 applied prior to times t6, t10 and t14 are generated, and those pulses 70 applied prior to the remaining times t4, t8, t12 and t16 are not generated. Being so designed, the timings of generating the pulse 70 are equidistant and the timing control circuit 14 is simple in construction. Another approach is allowed in which the pulse 70 is generated in a period when the information charge accumulation has progressed and the blooming is easy to occur, that is the latter half of the exposure period.

Also at timing t17 immediately before the frame transfer, a pulse 72 is superposed on the reference DC voltage V_{SL} of the substrate voltage Vsub, the discharge voltage V_{SH} is applied to the substrate and excessive charges are discharged from the potential wells of the image pickup section 10i. As a result, the blooming is suppressed, which is due to the difference between the amplitude of the clock signal φi in the exposure period E and the amplitudes the clock signals φi and φs in the frame transfer and the line transfer.

In the method of driving the image pickup apparatus, the blooming in the image pickup section 10i is suppressed by using the pulse 70 to be superposed on the substrate voltage Vsub. Because of this, it is possible for the reference DC voltage V_{SL} to be determined independently of the blooming suppressing. With the variation of the substrate voltage Vsub, the potential in the p-well 42 varies and furthermore the depth of the potential well (point B) from the substrate surface varies. Specifically, when the substrate voltage Vsub is decreased, the potential in the p-well 42 is shallow and the potential well moves to the substrate surface. As a result, the capacity of the transfer electrodes 32 and the charge transfer channel increases, the potential variation of the channel to the transfer clock signal increases and consequently the charge transfer capability increases. It is furthermore noted that in the image pickup apparatus, the line transfer is secured by setting the reference DC voltage V_{SL} to be low, while the blooming is suppressed by adjusting the discharge voltage V_{SH} of the pulse 70 and the charge transfer capability required for the frame transfer.

In the embodiment, the substrate voltage Vsub for the pulse 70 and the substrate voltage Vsub when the electronic shutter operation is performed are both set at the common discharge voltage V_{SH}. If necessary, those voltages may be different from each other.

In the potential well shift during the exposure period E, the timing control circuit 14 enlarges and reduces the period α, which defines the existing time of the potential wells under the transfer electrodes G1 to G3 according to an exposure control value Io output from the automatic exposure control circuit. The timing control circuit 14 sets the number of cycles of the potential well shift so that the period where the potential well formed under one transfer electrode continuously exists is below a predetermined upper value τmax. Specifically, in the driving method, as shown FIG. 8, the durations of the potential wells formed under the transfer electrodes G1 and G3 are each 2α and is longer than the duration of the potential well formed under the transfer electrode G2. Then, the timing control circuit 14 selects such a minimum number of cycles N_{c} that each of the durations of the potential wells formed under the transfer electrodes G1 and G3, for example, does not exceed the upper value τmax. Furthermore, the timing control circuit 14 enlarges and reduces the period a so that the clock operation time of the cycles N_{c} of the clock signal φi is equal to the exposure period E. For example, the timing control circuit 14 can define the period a in terms of a count number Nα of the reference clock signal CK. The exposure period E is controlled according to the exposure control value Io, as described above. Accordingly, the timing control circuit 14 may be arranged such that the number of cycles of N_{c} is determined depending on the exposure control value Io. The number of cycles of N_{c} and the period a may be determined through the operation processing by the timing control circuit 14. In an alternative, a table is used that contains the correspondences among the exposure control value Io, the number of cycles of N_{c} and the count number Nα. The table is searched for the number of cycles of N_{c} and the count number Nα by using an exposure control value Io that is set.

As described above, the method of driving a solid-state image pickup device, which is constructed according to the present invention, is applied to an image pickup section containing CCD shift registers for accumulating information charges generated in response to light exposure in potential wells being formed, corresponding to a plurality of pixels, by using a plurality of transfer electrodes arranged on the charge transfer channel region and a drain structure for discharging unnecessary information charges of the information charges from the charge transfer channel region into the drain region in response to a discharge voltage applied. The driving method includes an accumulation position shift process in which an on-electrode for forming the potential well in each pixel is changed within an exposure period among the plurality of transfer electrodes positioned at the pixel, to shift the accumulation position to which the information charges are accumulated within the pixel in response to shifting of the potential well formed by the on-electrode and a discharge process in which the discharge voltage is applied within the exposure period to the drain structure prior to execution of the accumulation position shift process, to discharge surplus information charges which exceed a predetermined upper limit of the amount of the information charges stored in the potential well. The potential barrier lowers when the potential well shifts between the transfer electrodes. In the driving method, the information charges are partially discharged from the potential well storing a lot of information charges to thereby suppress blooming. In the driving method, the discharge process is executed just prior to the time period in which the transfer electrodes adjacent to each other are concurrently made on-electrodes in the accumulation position shift process.

The driving method may be applied to an image pickup device constructed such that the CCD shift registers each have a buried channel structure including a surface side region of a first conductivity type provided in a surface of a semiconductor substrate and a foundation region of a second conductivity type formed under the surface region, and the drain structure is a vertical overflow drain structure in which a reverse side region of the first conductivity type, located under the foundation region, is the drain region, and the discharge voltage is applied to the drain region. Further, the driving method may be applied to a case where the discharge voltage is superposed as a pulse signal on a predetermined reference DC voltage, and the reference DC voltage is set according to a given transfer capability in the frame transfer of the information charge. The reference DC voltage is used for the blooming control by the vertical overflow drain, and affects the transfer capabilities of the charge transfer channels, except the image pickup section during the exposure period, specifically the transfer capabilities of the image pickup section and the storage section in the frame transfer and the storage section in the line transfer. In the driving method, the blooming suppression by the vertical overflow drain may be controlled by the discharge voltage applied by the pulse signal. There is no need to adjust the reference DC voltage for the blooming suppression. The reference DC voltage may be adjusted so as to secure satisfactory levels of the charge transfer capabilities of the charge transfer channels other than the image pickup section during the exposure period.

The image pickup apparatus has a solid-state image pickup device including CCD shift registers for accumulating information charges generated in response to light exposure in potential wells being formed, corresponding to a plurality of pixels, by using a plurality of transfer electrodes arranged on the charge transfer channel regions and a drain structure for discharging unnecessary information charges of the information charges from the charge transfer channel region into the drain region in response to a discharge voltage applied, and a driving circuit for driving the solid-state image pickup device. The driving circuit performs a accumulation position shift operation in which an on-electrode for applying on-voltage to each pixel is changed within an exposure period among the plurality of transfer electrodes positioned at the pixel, to shift the accumulation position to which the information charges are accumulated within the pixel in response to shifting of the potential well formed by the on-electrode. Furthermore, the driving circuit performs a discharge operation in which the discharge voltage is applied within the exposure period to the drain structure prior to execution of the accumulation position shift operation, to discharge surplus information charges which exceed a predetermined upper limit of the amount of the information charges stored in the potential well.

The driving circuit executes the discharge operation just prior to the time period in which the transfer electrodes adjacent to each other are concurrently made on-electrodes in the accumulation position shift operation.

In the image pickup apparatus, the CCD shift registers each have a buried channel structure including the surface side region of a first conductivity type provided in the surface of the semiconductor substrate and a foundation region of a second conductivity type, formed under the surface region and the drain structure is a vertical overflow drain structure in which a reverse side region of the first conductivity type, located under the foundation region, is the drain region and the discharge voltage is applied to the drain region.

The present invention successfully suppresses blooming, which tends to occur when the potential well is shifted within a pixel during the exposure period.

What is claimed is:

1. A driving method for a solid-state image pickup device having an image pickup section containing CCD shift registers for accumulating information charges generated in response to light exposure in potential wells formed corresponding to a plurality of pixels, by using a plurality of transfer electrodes arranged on the charge transfer channel region and a drain structure for discharging unnecessary information charges, of the information charges, from the charge transfer channel region into the drain region in response to an applied discharge voltage,
the method comprising:
an accumulation position shift process in which an on-electrode for forming the potential well in each pixel is changed within an exposure period among the plurality of transfer electrodes positioned at the pixel, to shift an accumulation position to which the information charges are accumulated within the pixel in response to shifting of the potential well formed by the on-electrode and
a discharge process in which the discharge voltage is applied within the exposure period to the drain structure prior to execution of the accumulation position shift process, to discharge surplus information charges which exceed a predetermined upper limit of the amount of the information charges stored in the potential well.

2. The driving method according to claim 1, wherein the discharge process is executed just prior to a time period in which the transfer electrodes adjacent to each other are concurrently made the on-electrodes in the accumulation position shift process.

3. The driving method according to claim 1, wherein the CCD shift registers each have a buried channel structure including a surface side region of a first conductivity type provided in a surface of a semiconductor substrate and a foundation region of a second conductivity type, formed under the surface region and the drain structure is a vertical overflow drain structure in which a reverse side region of the first conductivity type, located under the foundation region, is the drain region and the discharge voltage is applied to the drain region.

4. The driving method according to claim 3, wherein the discharge voltage is superposed as a pulse signal on a predetermined reference DC voltage and the reference DC voltage is set according to a given transfer capability in a frame transfer of the information charge.

5. An image pickup apparatus having a solid-state image pickup device including CCD shift registers for accumulating information charges generated in response to light exposure in potential wells being formed, corresponding to a plurality of pixels, by using a plurality of transfer electrodes arranged on charge transfer channel regions and a drain structure for discharging unnecessary information charges, of the information charges, from the charge transfer channel regions into the drain region in response to an applied discharge voltage, and a driving circuit for driving the solid-state image pickup device,
wherein the driving circuit performs a accumulation position shift operation in which an on-electrode for forming the potential well in each pixel is changed within an exposure period among the plurality of transfer electrodes positioned at the pixel, to shift an accumulation position to which the information charges are accumulated within the pixel in response to shifting of the potential well formed by the on-electrode, and a discharge operation in which the discharge voltage is applied within the exposure period to the drain structure prior to execution of the accumulation position shift operation, to discharge surplus information charges which exceeds a predetermined upper limit of the amount of the information charges stored in the potential well.

6. The image pickup apparatus according to claim 5, wherein the driving circuit executes the discharge operation just prior to the time period in which the transfer electrodes adjacent to each other are concurrently made the on-electrodes in the accumulation position shift operation.

7. The image pickup apparatus according to claim 5, wherein the CCD shift registers each have a buried channel structure including a surface side region of a first conductivity type provided in a surface of a semiconductor substrate and a foundation region of a second conductivity type, formed under the surface region and
the drain structure is a vertical overflow drain structure in which a reverse side region of the first conductivity type, located under the foundation region, is the drain region and the discharge voltage is applied to the drain region.
